(19) United States
(12) Patent Application Publication
(10) Pub. No.: US 2023/0072923 A1
(43) Pub. Date: Mar. 9, 2023

(54) SUPERVISED MACHINE LEARNING BASED MEMORY AND RUNTIME PREDICTION USING DESIGN AND AUXILIARY CONSTRUCTS

(71) Applicant: Synopsys, Inc., Mountain View, CA (US)

(72) Inventors: Sachin BANSAL, Noida (IN); Bhaskar PAL, Cupertino, CA (US); Arun Kumar SHREEVASTAVA, Kolkata (IN); Gaurav PRATAP, Noida (IN); Hasindu RAMANAYAKE, Kandy (LK)

(21) Appl. No.: 17/898,088

(22) Filed: Aug. 29, 2022

Related U.S. Application Data
(60) Provisional application No. 63/239,910, filed on Sep. 1, 2021.

(51) Int. Cl. G06N 20/00; G06F 30/392

(52) U.S. Cl. CPC G06N 20/00; G06F 30/392

(57) ABSTRACT

A machine learning (ML) model is described herein that predicts computational resource requirements (e.g., a memory and/or runtime metric) for evaluating an integrated circuit (IC) design (e.g., static verification) based on design features extracted from the IC design and auxiliary features related to the IC design. The model may be used to predict the metric for sub-blocks of the IC design. A platform selector may select one of multiple platforms on which to evaluate the IC design or sub-blocks of the IC design based on the predicted metric(s) and specifications of the platforms. The model may be trained to correlate a combination of design features extracted from training IC designs and auxiliary features related to the training IC designs, with metrics of computational resources used in evaluation of the training IC designs, such as with a multiple-linear-regression-based supervised learning technique.

### CROSS REFERENCE TO RELATED APPLICATION

This application claims the benefit of U.S. Provisional Application for Patent no. 63/239,910, titled “Supervised Machine Learning Based Memory and Runtime Prediction Using Design and Auxiliary Constructs.” filed Sep. 1, 2021, which is incorporated herein by reference in its entirety.

### TECHNICAL FIELD

The present disclosure relates to supervised machine learning based memory and runtime prediction using design and auxiliary constructs.

### BACKGROUND

Electronic design automation (EDA) is a category of computing tools for designing, verifying, and simulating operations of semiconductor-based integrated circuits (ICs). EDA may be computationally expensive in terms of runtime, memory requirements, power consumption, and/or other factors.

A variety of computing platforms may be available for an EDA task, such as in a cloud or distributed computing environment. One of the computing platforms may be more suitable than others based on complexities of a particular IC design and specifications of the respective computing platforms.

### SUMMARY

Techniques for supervised machine learning based memory and runtime prediction using design and auxiliary constructs are described.

One example is method that includes extracting design features of a training set of IC designs, selecting a one or more of the extracted design features based on an extent to which the extracted design features correlate to a metric of a processing resource utilized to evaluate the IC designs, and training a machine learning (ML) model to correlate the selected design features of the IC designs with the metric of the IC designs.

In other examples, the selected design features may be extracted from a new IC design, and the trained model may be used to predict the metric for the new IC design based on the selected design features extracted from the new IC design.

Another example described herein is a system that includes a computing platform configured to extract design features of a training set of IC designs, select a one or more of the extracted design features based on an extent to which the extracted design features correlate to a metric of a processing resource utilized to evaluate the IC designs, select one or more auxiliary features of the IC designs based on an extent to which the auxiliary features correlate to the metrics of the IC designs, and train an artificial intelligence/machine learning (AI/ML) model to correlate a combination of the selected design features of the IC design and the selected auxiliary features of the new IC design with the metric of the IC designs.

Another example described herein is a system that includes a computing platform configured to extract design features of a training set of IC designs, select a one or more of the extracted features based on an extent to which the extracted design features correlate to a metric of a processing resource utilized to evaluate the IC designs, select one or more auxiliary features of the IC designs based on an extent to which the auxiliary features correlate to the metrics of the IC designs, train an artificial intelligence/machine learning (AI/ML) model to correlate a combination of the selected design features of the IC designs and the selected auxiliary features of the IC designs with the metric of the IC designs, extract the selected design features from a new IC design, and use the trained model to predict the metric for the new IC design based on the combination of the selected design features of the new IC design and the selected auxiliary features of the new IC design.

In yet another example, is a non-transitory computer readable medium having instructions, which when executed by a processing device, cause the processing device to extract design features of a training set of IC designs, select a one or more of the extracted features based on an extent to which the extracted design features correlate to a metric of a processing resource utilized to evaluate the IC designs, select one or more auxiliary features of the 1C designs based on an extent to which the auxiliary features correlate to the metrics of the IC designs, train a machine learning (ML) model to correlate a combination of the selected design features of the IC designs and the selected auxiliary features of the IC designs with the metric of the IC designs, extract the selected design features from a new IC design, and use the trained model to predict the metric for the new IC design based on the combination of the selected design features of the new IC design and the selected auxiliary features of the new IC design

### BRIEF DESCRIPTION OF DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 is a block diagram of a computing platform that includes an artificial intelligence/machine learning (A/ML) model that predicts one or more metrics of a computational resource needed to evaluate an integrated circuit (IC) design.

FIG. 2 is a block diagram of the computing platform in which the AI/ML model is trained based on design features extracted from a training set of IC designs and resource metrics of the IC designs.

FIG. 3 is a block diagram of the computing platform in which the AI/ML model is trained based on a combination of the design features and auxiliary features.

FIG. 4 is a block diagram of the computing platform in which the AI/ML model predicts a metric(s) for a new IC design.

FIG. 5 is a block diagram of the computing platform in which the AI/ML model predicts the metric for sub-blocks of an IC design.

FIG. 6 is a block diagram of the computing platform, including a platform selector that selects one of multiple platforms on which to evaluate an IC design or sub-blocks of an IC design based on predicted metric(s).

FIG. 7 is a flowchart of a method of training an AI/ML model to predict a metric(s) of a computational resource needed to evaluate an IC design.

FIG. 8 is a flowchart of another method of training an AI/ML model to predict a metric(s) of a computational resource needed to evaluate an IC design.

FIG. 9 is a flowchart of a method of using an AI/ML model to predict a metric(s) of a computational resource needed to evaluate an IC design.

FIG. 10 is flowchart of another method of using an AI/ML model to predict a metric(s) of a computational resource needed to evaluate sub-blocks of an IC design.

FIG. 11 is flowchart of a method of using an AI/ML model to predict a metric(s) of a computational resource needed to evaluate an IC design, and selecting a platform on which to evaluate the IC design based on the predicted metric(s) and specifications of the respective platforms.

FIG. 12 depicts a flowchart of various processes used during the design and manufacture of an integrated circuit in accordance with some embodiments of the present disclosure.

FIG. 13 depicts a diagram of an example computer system in which embodiments of the present disclosure may operate.

### DETAILED DESCRIPTION

Aspects of the present disclosure relate to supervised machine learning based memory and runtime prediction using design and auxiliary constructs.

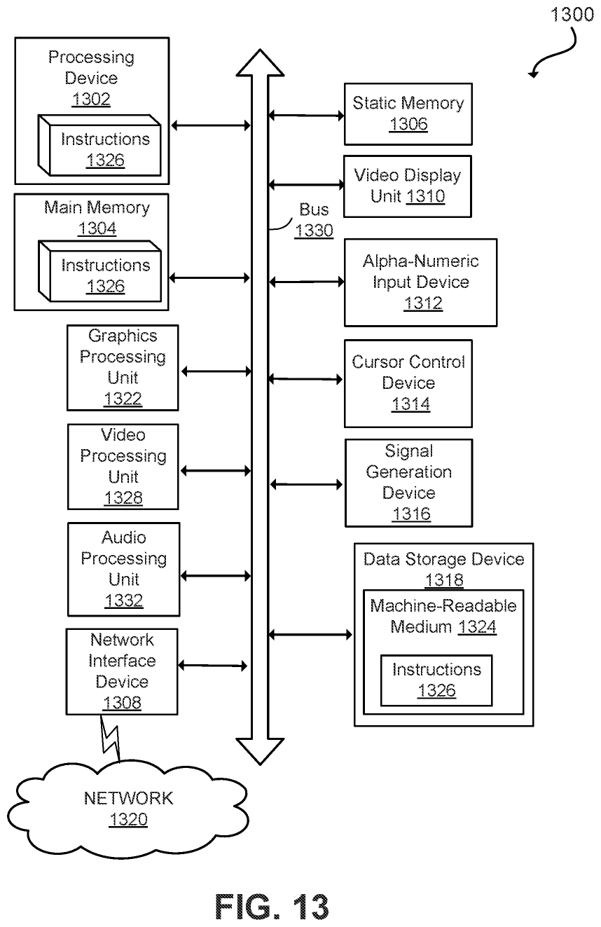

For illustrative purposes, techniques are described herein with respect to static design verification. Techniques disclosed herein are not, however, limited to static design verification. A static design verification tool analyzes code of an IC design (e.g., hardware description language (HDL) code) to ensure that the code meets desired requirements or adheres to accepted coding practices. HDL is a computer language used to describe structure and behavior of integrated circuits (ICs). Static design verification is one of multiple stages of electronic design automation (EDA). EDA is described further below with reference to FIG. 13.

Static verification tools are computationally expensive in terms of runtime, memory requirements, power consumption, and/or other factors. Where multiple computing platforms are available for static design verification, such as in a cloud and/or distributed computing environment, one of the computing platforms may be more suitable than others for static verification (e.g., in view of computing resource needs of the IC design, specifications of the respective computing platforms, and costs associated with the respective computing platforms). Each computing platform may incur a cost based on capabilities/specifications of the computing platform. If a task is assigned to an over-qualified computing platform, unnecessary costs may be incurred. If a task is assigned to an under-qualified computing platform, the task may fail to execute properly, and the time and costs incurred for use of the platform may be wasted. It would thus be useful to predict computing resource requirements of an IC design in order to select an appropriate platform on which to verify the IC design. Due to the complexities involved, a human mind cannot practically predict computational resource requirements of an IC design with a useful degree of accuracy.

Disclosed herein is an artificial intelligence/machine learning (AI/ML) model that predicts computational resource requirements (e.g., a memory and/or runtime metric) for evaluating an IC design (e.g., static verification) based on design features extracted from the IC design and auxiliary features related to the IC design. The artificial intelligence/machine learning (AI/ML) model may simply be a machine learning (ML) model. The model may be used to predict the metric for sub-blocks of the IC design. A platform selector may select one of multiple platforms on which to evaluate the IC design or sub-blocks of the IC based on the predicted metric(s) and specifications of the platforms. The model may be trained to correlate a combination of design features extracted from training IC designs and auxiliary features related to the training IC designs, with computation resources used in evaluation of the training IC designs, such as with a multiple-linear-regression-based supervised learning technique.

Technical advantages of techniques disclosed herein include, without limitation, improved efficiency and accuracy in predicting computational resource requirements for evaluating an IC design.

Technical advantages further include improved efficiency and accuracy in selecting a computing platform on which to evaluate an IC design.

Techniques disclosed herein may be useful to dynamically choose an optimal computing platform (e.g., in a distributed environment) to match memory and runtime requirements of an IC design based on features of the IC design, alone or in combination with auxiliary information related to the IC design. Dynamic selection of a computing platform may reduce the chance of scheduling a verification run of a design to a sub-optimal machine configuration, which might otherwise lead to an aborted run because of low memory/CPU availability.

Techniques disclosed herein may be useful to utilize EDA tools, including static verification tools, in distributed/cloud computing environments, such as to reduce turn-around times and/or increase/optimize utilization of computing platform resources.

The term “distributed system” refers to a system whose components are located on different networked computers, which communicate and coordinate their actions by passing messages to one another from any system. The components interact with one another in order to achieve a common goal.

The term “cloud computing” refers to on-demand computer system resources, such as data storage (cloud storage) and computing power, without direct active management by the user. Cloud providers typically use a “pay-as-you-go” model, which makes it very important to use the resources judiciously for the given design or task.

As there may be many machines in a distributed environment, of varying abilities/resources, predicting memory and runtime requirements of an IC design may be very useful.

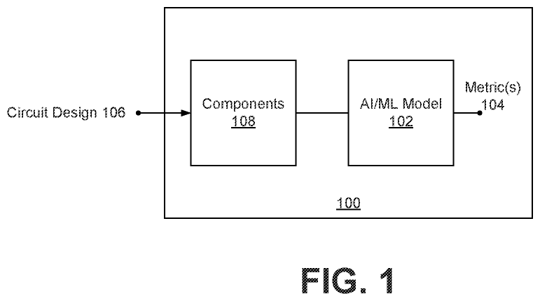

FIG. 1 is a block diagram of a computing platform 100 that includes an artificial intelligence/machine learning (AI/ML) model 102 that predicts one or more metrics 104 of a computational resource needed to evaluate an IC design 106. IC design 106 may represent, without limitation, a system-on-a-chip (SoC). Computing platform 100 may include fixed-function or fixed-logic circuitry, a processor and memory, and combinations thereof.

Metric(s) 104 may relate to computational resources needed for static verification of IC design 106. Metric(s) 104 may include, without limitation, a runtime metric (e.g., a processor or CPU metric, such as how long it takes to perform the evaluation) and/or a memory metric (e.g., memory usage/requirements for the evaluation).

Computing platform 100 further includes components 108 for training and using AI/ML model 102, such as described examples below.

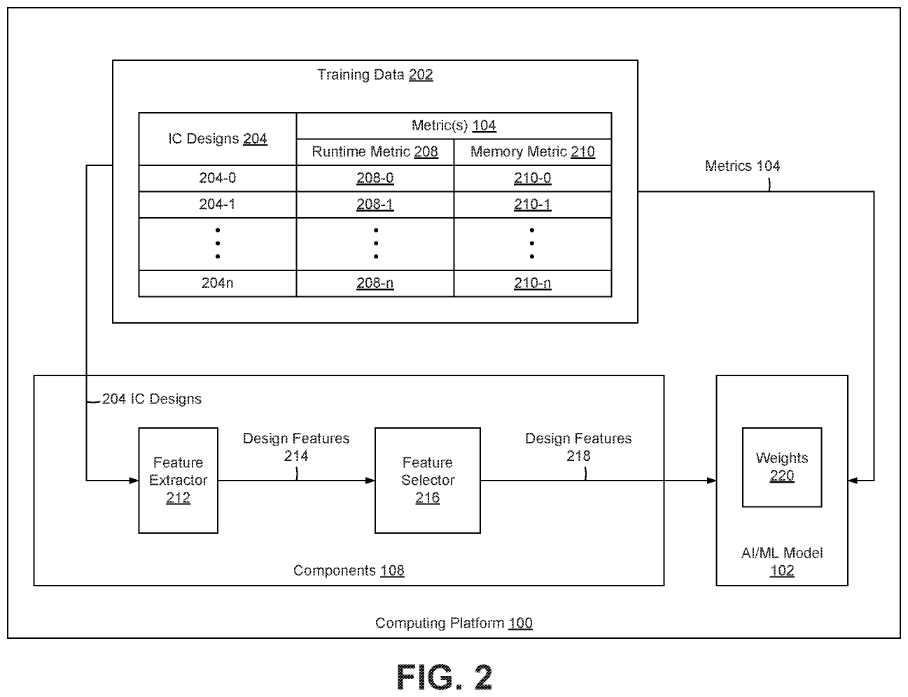

FIG. 2 is a block diagram of computing platform 100 in which components 108 include components for training AI/ML model 102 with training data 202. In the example of FIG. 2, training data 202 includes IC designs 204-0 through 204-n, collectively referred to as IC designs 204. IC designs 204 may include machine readable code and/or data, such as HDL code. IC designs 204 may include tens, hundreds, or thousands of designs.

Training data 202 further includes metric(s) 104 for IC designs 204, which are utilized as labels for supervised training of AI/ML model 102. In the example of FIG. 2, metric(s) 104 include a runtime metric 208 and a memory metric 210. Metric(s) 104 may be obtained or determined from actual and/or simulated design verification processes performed on IC designs 204.

In the example of FIG. 2, components 108 include a feature extractor 212 that extracts design constructs or design features 214 from IC designs 204. Example design features are provided further below. IC designs 204 may include practically innumerable features, and feature extractor 212 may extract a subset of the available features based on domain knowledge (e.g., user-input) and/or heuristics.

Design features 214 may, nevertheless, be numerous, and components 108 may further include a feature selector 216 that selects a subset of one or more design features 214, illustrated here as design features 218. Feature selector 216 may select and/or filter design features 218 based on an extent to which design features 218 correlate to metrics 206. In an embodiment, functions of feature selector 216 are performed in-whole or in-part within AI/ML model 102.

In FIG. 2, computing platform 100 trains AI/ML model 102 to correlate design features 218 with metrics 206. Stated another way, AI/ML model 102 learns to compute metrics 206 from selected design features 218. AI/ML model 102 may, for example, iteratively or repetitively adjust or tune weights 220 associated with design features 218 until an algorithm that employs the weights can accurately compute metric(s) 104 from design features 218. Conceptually, for each IC design 204, the algorithm may multiply design features 218 by the respective weights, sum the products of the multiplications, compare the sum to the respective metric(s) 104, and adjust the weights to reduce a difference between the sum and the metric(s) 104.

Where A/ML model 102 is to predict multiple types of metrics (e.g., runtime metric 208 and memory metric 210), feature selector 216 may select a set of design features 218 for each metric type, and AI/ML model 102 may learn a correlation (e.g., tune a set of weights) for each metric type.

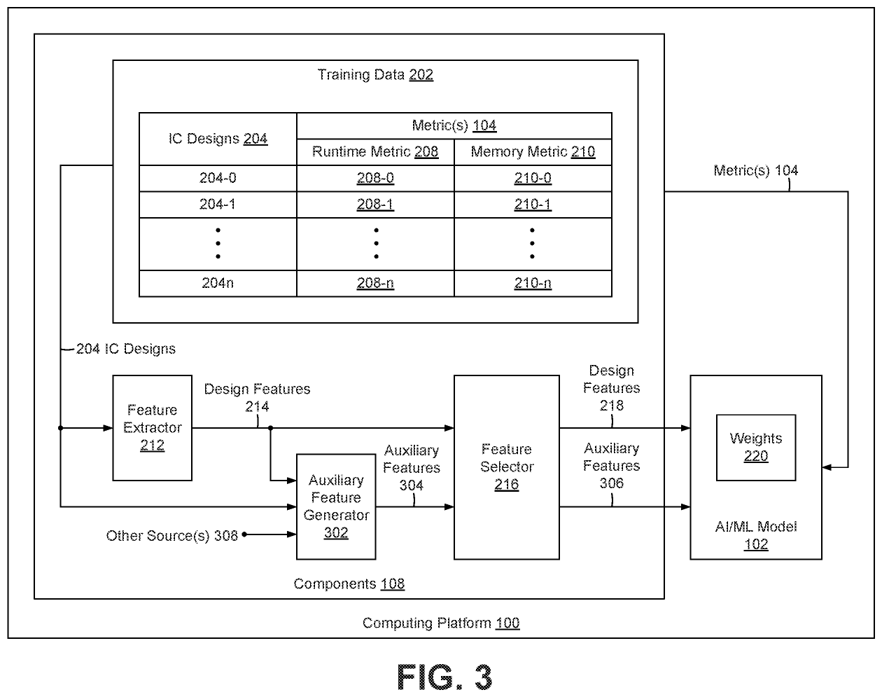

In an embodiment, computing platform 100 trains AI/ML model 102 based on a combination of design features 218 and auxiliary features related to IC designs 204, such as described below with reference to FIG. 3.

FIG. 3 is a block diagram of computing platform 100 in which AI/ML model 102 is trained based on a combination of design features 218 and auxiliary features 306. In the example of FIG. 3, components 108 further include an auxiliary feature generator 302 that generates (e.g., retrieves, extracts, and/or computes) auxiliary features 304. In this example, feature selector 216 selects a subset of one or more auxiliary features 304 as auxiliary features 306, and AI/ML model 102 learns to correlate a combination of design features 218 and auxiliary features 306 with metric(s) 104. Stated another way, AI/ML model 102 learns to compute metric(s) 104 from the combination of design features 218 and auxiliary features 306.

Auxiliary feature generator 302 may generate auxiliary features 304 based on IC designs 204, design features 214, and/or information obtained from other sources 308. Example auxiliary features are provided further below.

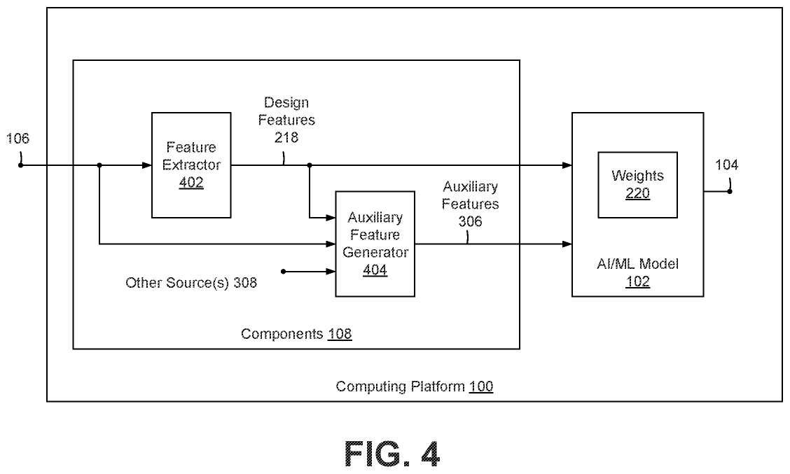

When AI/ML model 102 is sufficiently trained, AI/ML model 102 may be used to predict metric(s) 104 for IC design 106, such as described below with reference to FIG. 4.

FIG. 4 is a block diagram of computing platform 100 in which components 108 include components to use AI/ML model 102 to predict metric(s) 104 for IC design 106. In the example of FIG. 4, components 108 include a feature extractor 402 that extracts the selected design features 218 from IC design 106, and an auxiliary feature generator 404 that generates auxiliary features 306 based on IC design 106, design features 218, and/or information from other sources 308. Feature extractor 402 and auxiliary feature generator 404 may be configured based on selections made by feature selector 216 (FIG. 3) during training of AI/ML model 102. In an embodiment, feature extractor 402 and auxiliary feature generator 404 represent modified versions of feature extractor 212 and auxiliary feature generator 302.

During use of AI/ML model 102, feature selector 216 (FIG. 2) may be omitted or bypassed.

In the foregoing examples, AI/MI model 102 is trained and used on the same computing platform (i.e., computing platform 100) for illustrative purposes. In an embodiment, AI/ML model 102 is trained on computing platform 100 and used on one or more other computing platforms.

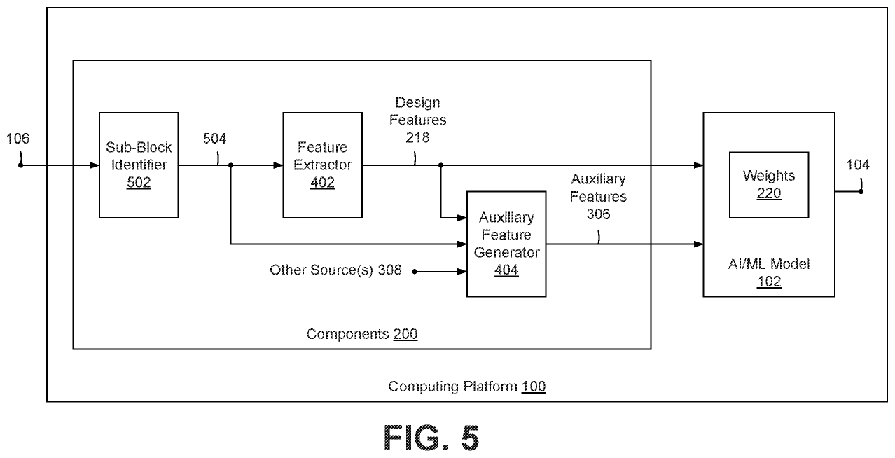

AI/ML model 102 may be used to predict metric(s) 104 for sub-blocks of IC design 106, such as described below with reference to FIG. 5.

FIG. 5 is a block diagram of computing platform 100 in which components 108 further include a sub-block identifier 502 that segments IC design 106 into sub-blocks 504 (e.g., based on timing domains, power domains, and/or other factor(s)). In the example of FIG. 5, feature extractor 402 extracts design features 218, auxiliary feature generator 404 generates auxiliary features 306, and AI/ML model 102 predicts metric(s) 104, for sub-blocks 504. Example uses or applications of predicted metric(s) 104 for sub-blocks 504 are provided further below.

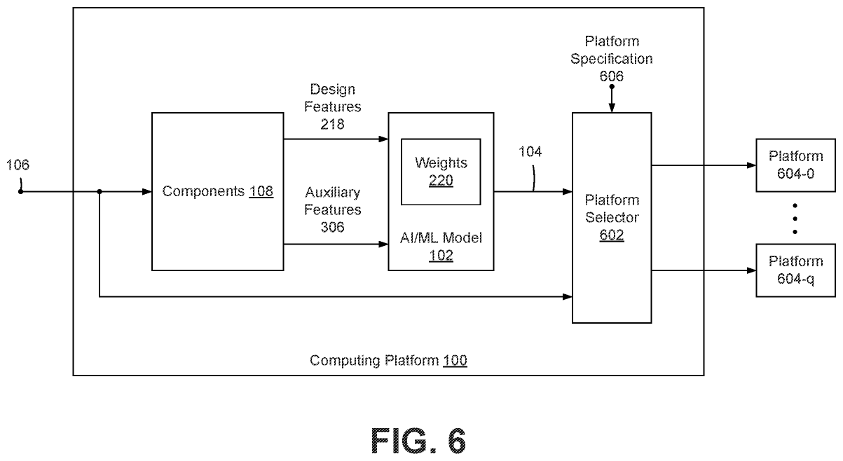

Predicted metric(s) 104 may be useful in one or more of a variety of applications including, without limitation, selecting a platform on which to evaluate IC design 106 and/or a sub-block 504 of IC design 106. Examples are provided below with reference to FIG. 6.

FIG. 6 is a block diagram of computing platform 100, further including a platform selector 602 that selects one of multiple platforms 604 on which to evaluate IC design 106 or sub-blocks 504 of IC design 106, based on predicted metric(s) 104. Platforms 604 may represent computing platforms of a cloud and/or distributed processing environment.

Example methods of training and using an AI/ML model to predict a metric(s) of a computational resource needed to evaluate an IC design are provided below.

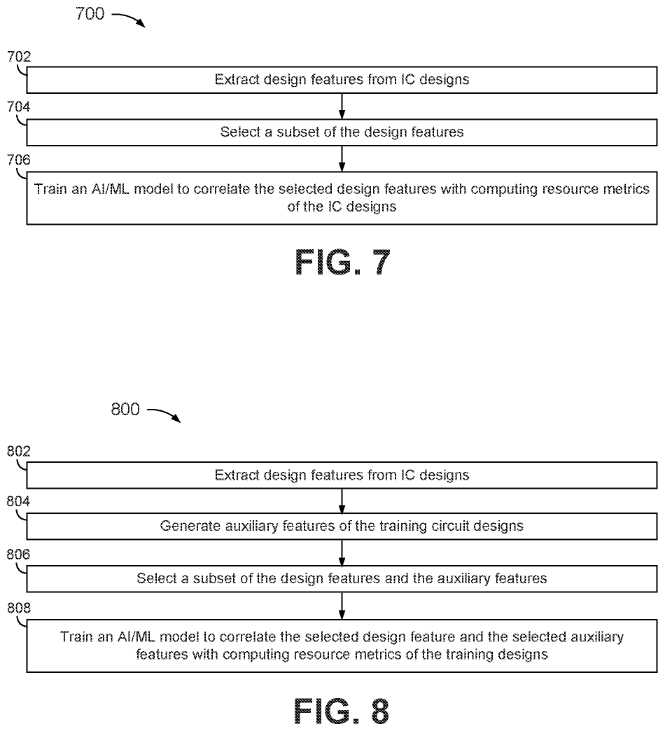

FIG. 7 is a flowchart of a method 700 of training an AI/ML model to predict a metric(s) of a computational resource needed to evaluate an IC design. Method 700 is described below with reference to FIG. 2 for illustrative purposes.

At 702, feature extractor 212 extracts design features 214 from IC designs 204. Design features 214 may include features that impact runtime and/or memory of a verification run. Design features 214 may include, without limitation, a number of instances, pins, ports, nets, and/or a number of hierarchies of IC designs 204. Design features 214 may further include dependent features, such as a number of libraries included and/or various type of cells, such as macro, pad, and/or power management cells, buffers, and/or inverters.

At 704, feature selector 216 selects one or more design features 218 from design features 214.

At 706, computing platform 100 trains AI/ML model 102 to correlate design features 218 with one or more computing resource metric(s) 104 of IC designs 204.

Computing platform 100 may train AI/ML model 102 in a supervised learning fashion. Supervised learning uses labeled training data to train a model to classify data or predict outcomes. Labeled training data includes independent variables (i.e., inputs, illustrated here as design features 218 and auxiliary features 306), and corresponding dependent variables (i.e., labels or outputs, illustrated here as metric(s) 104).

Computing platform 100 may use regression to train AI/ML model 102. Regression techniques include linear regression, logistical regression, and polynomial regression. Linear regression is useful to identify the relationship between a dependent variable and one or more independent variables and is typically leveraged to make predictions about future outcomes. Simple linear regression is used when there is one independent variable and one dependent variable. For multiple independent variables, multiple linear regression is used. For either type of linear regression, a best fit line is sought, which may be computed with least squares.

FIG. 8 is a flowchart of a method 800 of training an AI/ML model to predict a metric(s) of a computational resource needed to evaluate an IC design. Method 800 is described below with reference to FIG. 3 for illustrative purposes.

At 802, feature extractor 212 extracts design features 214 from IC designs 204, such as described above with respect to 702 in FIG. 7.

At 804, auxiliary feature generator 302 generates auxiliary features 304 based on IC designs 204, design features 214, and/or information retrieved from one or more other sources 308.

Auxiliary features 304 may include, without limitation, operational information related to an IC: design (e.g., power consumption, area consumption, and/or timing information), and/or design constraints related to an IC design (e.g., power, area, and/or timing constraints). Auxiliary feature generator 302 may extract auxiliary features 304 from a machine-readable file(s).

As an example, auxiliary feature generator 302 may extract power information for an IC design from a machine-readable file formatted in accordance with a unified power format (UPF). UPF is a power format specification to implement low power techniques in a design flow. UPF is designed to reflect the power intent of a design at a relatively high level. UPF scripts may describe power intent such as which power rails to be routed to individual blocks, when blocks are expected to be powered up or shut down, how voltage levels should be shifted between two different power domains, and type of measures taken for retention registers and memory cells contents if the primary power supply to a domain is removed. A UPF file may be generated by an electronic design automation (EDA) tool based on an IC design.

A UPF file may include features that impact runtime and memory needed to perform a design verification of an IC, such as supply network complexity in terms of power domains, supply nets, supply ports, and/or power state tables. Power management of an IC design may be specified or in terms of isolation, level shifter, retention, and power switch. A UPF file may also include query commands and/or find_objects, which impact runtime and memory for an IC design.

As another example, auxiliary feature generator 302 may extract design constraints related to an IC design from a machine-readable file(s) formatted in accordance with a Synopsis Design Constraint (SDC) format, developed by Synopsis, Inc., of Mountain View, Calif.

At 806, feature selector 216 selects one or more design features 218 from design features 214, and one or more auxiliary features 306 from auxiliary features 304. Feature selector 216 may select design features 218 based on an extent to which design features 218 correlate to metrics 206. Stated another way, feature selector 216 may filter out design features 214 that do not sufficiently correlate to metrics 206, or that are deemed outliers. Feature selector 216 may filter or remove an entire IC design 204 from training data 202 if features of the IC design or a metric(s) associated with the IC design is deemed an outlier. Design features 218 may be further fine-tuned or filtered by AI/ML model 102 based on, for example, data analysis/correlation and/or data cleansing. In an embodiment, functions of feature selector 216 are performed in-whole or in-part within AI/ML model 102. Feature selection/data cleansing may be useful to reduce downstream consumption of computational resources (i.e., in training and/or using AI/ML model 102).

At 808, computing platform 100 trains AI/ML model 102 is to correlate a combination of design features 218 and auxiliary features 306 with metric(s) 104 of IC designs 204, such as described above with respect to 706 in FIG. 7.

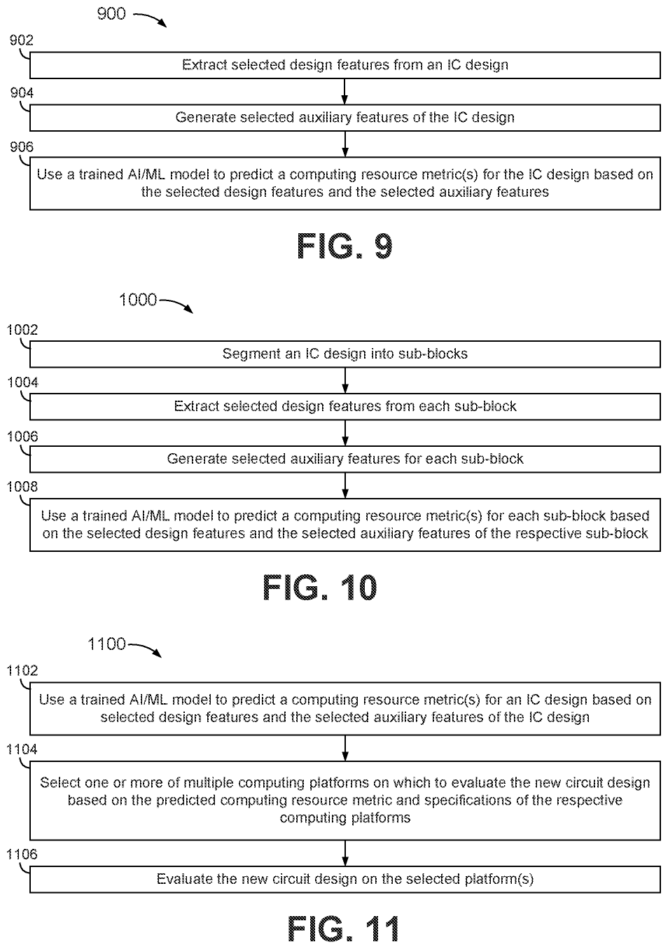

FIG. 9 is a flowchart of a method 900 of using an AI/ML model to predict a metric(s) of a computational resource needed to evaluate an IC design. Method 900 is described below with reference to FIG. 4 for illustrative purposes.

At 902, feature extractor 402 extracts design features 218 from 1C design 106.

At 904, auxiliary feature generator 404 generates auxiliary features 306 for IC design 106 based on IC design 106, design features 218, and/or information retrieved from one or more other sources 308.

At 906, A/ML model 102 predicts metric(s) 104 for IC design 106 based on design features 218 of IC design 106 and auxiliary features 306 of IC design 106, and weights 220. Conceptually, for each metric 104, AI/ML model 102 may multiply a set of design features 218 of IC design 106 by a respective set of weights, and sum the products of the multiplications to provide the metric 104.

In an embodiment, generation of auxiliary features 306 at 904 is omitted and AI/ML model 102 predicts metric(s) 104 for IC design 106 without consideration of auxiliary features 306.

FIG. 10 is flowchart of a method 1000 of using an AI/ML model to predict a metric(s) of a computational resource needed to evaluate sub-blocks of an IC design. Method 1000 is described below with reference to FIG. 5 for illustrative purposes.

At 1002, sub-block identifier 502 segments IC design 106 into sub-blocks 504. Sub-block identifier 502 may segment IC design 106 into sub-blocks 504 based on timing domains, power domains, and/or other factor(s). Sub-block identifier 502 may identify sub-blocks 504 that can be converted into abstract models in a distributed environment based on IC design 106, alone or in combination with auxiliary constructs (e.g., auxiliary features 306). Sub-block identifier 502 may create abstraction models for sub-blocks while running IC design 106 (e.g., a SoC) in a distributed paradigm.

At 1004, feature extractor 402 extracts design features 218 from each sub-block 504.

At 1006, auxiliary feature generator 404 generates auxiliary features 306 for each sub-block 504 based on the respective sub-block 504, design features 218, and/or information retrieved from one or more other sources 308.

At 1008, AI/ML model 102 predicts metric(s) 104 for sub-blocks 504 based on design features 218 and auxiliary features 306 of the respective sub-blocks 504.

FIG. 11 is flowchart of a method 1100 of using an AI/ML model to predict a metric(s) of a computational resource needed to evaluate an IC design, and selecting a platform on which to evaluate the IC design based on the predicted metric(s) and specifications of the respective platforms. Method 1100 is described below with reference to FIG. 6 for illustrative purposes.

At 1102, AI/ML model 102 predicts metric(s) 104 for IC design 106 based on selected design features 218 and selected auxiliary features 306.

At 1104, platform selector 602 selects one of multiple platforms 604 on which to evaluate IC design 106 based on predicted metric(s) 104 and platform specifications 606 of the respective computing platforms (e.g., memory and/or run-time related specifications).

At 1106, the selected platform 604 performs a verification process on IC design 106. The verification process may include a static verification process in which the selected platform 604 analyzes code of an IC design (e.g., HDL code) to ensure that standard coding practices have been adhered to.

Static verification techniques include timing analysis, equivalence checking, data flow analysis, model checking, abstraction interpretation, assertion usage, register-transfer level (RTL) lint, static RTL checks (which include low power structure verification and clock domain crossing verification), sequential formal checks, application-specific formal solutions, and assertion-based formal property verification. Static verification tools include a suite of static verification tools developed by Synopsys, Inc., of Mountain View, Calif.

In an embodiment, AI/ML model 102 predicts metric(s) 104 for each sub-block 504, such as described above with reference to FIG. 10, and platform selector 602 selects one of platforms 604 for each sub-block 504 based on the respective metric(s) 104 and platform specifications 606.

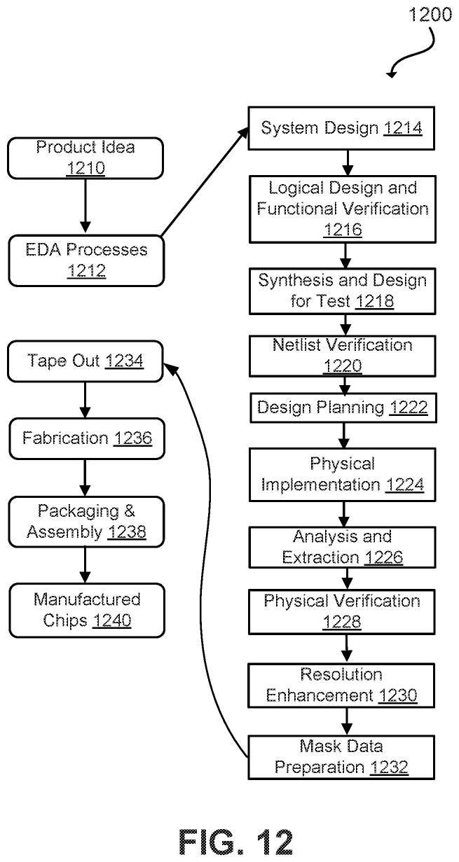

FIG. 12 illustrates an example set of processes 1200 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 1210 with information supplied by a designer, information which is transformed to create an article of manufacture that uses a set of EDA processes 1212. When the design is finalized, the design is taped-out 1234, which is when artwork (e.g., geometric patterns) for the integrated circuit is sent to a fabrication facility to manufacture the mask set, which is then used to manufacture the integrated circuit. After tape-out, a semiconductor die is fabricated 1236 and packaging and assembly processes 1238 are performed to produce the finished integrated circuit 1240.

Specifications for a circuit or electronic structure may range from low-level transistor material layouts to high-level description languages. A high-level of representation may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding systems of that layer (e.g., a formal verification system). A design process may use a sequence depicted in FIG. 12. The processes described by be enabled by EDA products (or EDA systems).

During system design 1214, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 1216, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 1218, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 1220, the netlist is checked for compliance with timing constraints and for correspondence with the HDL code. During design planning 1222, an overall floor plan for the integrated circuit is constructed and analyzed for timing and top-level routing.

During layout or physical implementation 1224, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 1226, the circuit function is verified at the layout level, which permits refinement of the layout design. During physical verification 1228, the layout design is checked to ensure that manufacturing constraints are correct, such as DRC constraints, electrical constraints, lithographic constraints, and that circuitry function matches the HDL design specification. During resolution enhancement 1230, the geometry of the layout is transformed to improve how the circuit design is manufactured.

During tape-out, data is created to be used (after lithographic enhancements are applied if appropriate) for production of lithography masks. During mask data preparation 1232, the ‘tape-out’ data is used to produce lithography masks that are used to produce finished integrated circuits.

A storage subsystem of a computer system (such as computer system 1300 of FIG. 13) may be used to store the programs and data structures that are used by some or all of the EDA products described herein, and products used for development of cells for the library and for physical and logical design that use the library.

FIG. 13 illustrates an example machine of a computer system 1300 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1300 includes a processing device 1302, a main memory 1304 (e.g., read-only memory (ROM), flash memory, dynamic random access memory (DRAM) such as synchronous DRAM (SDRAM), a static memory 1306 (e.g., flash memory, static random access memory (SRAM), etc.), and a data storage device 1318, which communicate with each other via a bus 1330.

Processing device 1302 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1302 may also be one or more special-purpose processing devices such as an application specific integrated circuit (ASIC), a field programmable gate array (FPGA), a digital signal processor (DSP), network processor, or the like. The processing device 1302 may be configured to execute instructions 1326 for performing the operations and steps described herein.

The computer system 1300 may further include a network interface device 1308 to communicate over the network 1320. The computer system 1300 also may include a video display unit 1310 (e.g., a liquid crystal display (LCD) or a cathode ray tube (CRT)), an alphanumeric input device 1312 (e.g., a keyboard), a cursor control device 1314 (e.g., a mouse), a graphics processing unit 1322, a signal generation device 1316 (e.g., a speaker), graphics processing unit 1322, video processing unit 1328, and audio processing unit 1332.

The data storage device 1318 may include a machine-readable storage medium 1324 (also known as a non-transitory computer-readable medium) on which is stored one or more sets of instructions 1326 or software embodying any one or more of the methodologies or functions described herein. The instructions 1326 may also reside, completely or at least partially, within the main memory 1304 and/or within the processing device 1302 during execution thereof by the computer system 1300, the main memory 1304 and the processing device 1302 also constituting machine-readable storage media.

In some implementations, the instructions 1326 include instructions to implement functionality corresponding to the present disclosure. While the machine-readable storage medium 1324 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 1302 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method, comprising:
extracting design features of a training set of integrated circuit (IC) designs;
selecting a one or more of the extracted design features based on an extent to which the extracted design features correlate to a metric of a processing resource utilized to evaluate the IC designs; and
training a machine learning (ML) model to correlate the selected design features of the IC designs with the metric of the processing resource utilized to evaluate the IC designs.

2. The method of claim 1, wherein the metric comprises a memory metric and/or a runtime metric.

3. The method of claim 1, wherein:
the selecting comprises selecting one or more auxiliary features of the IC designs based on an extent to which the auxiliary features correlate to the metrics of the IC designs;
the training comprises training the ML model to correlate a combination of the selected design features of the IC designs and the selected auxiliary features of the IC designs with the metrics of the IC designs; and
the using comprises using the trained model to predict the metric for the new IC design based on the combination of the selected design features of the new IC design and the selected auxiliary features of the new IC design.

4. The method of claim 3, wherein the auxiliary features comprise:
design constraints of the IC designs; and/or
power consumption information of the IC designs.

5. The method of claim 1, further comprising:
selecting one or more of multiple computing platforms on which to evaluate the new IC design based on the predicted metric and specifications of the computing platforms.

6. The method of claim 1, further comprising segmenting the IC design into sub-blocks, wherein the using comprises:
using the trained model to predict the metric for the sub-blocks of the new IC design.

7. The method of claim 6, further comprising:
selecting one of multiple computing platforms on which to evaluate one of the sub-blocks of the new IC design based on the predicted metric of the sub-block and specifications of the computing platforms.

8. The method of claim 1, wherein the training comprises:
training the ML model to correlate the selected design features of the IC designs with the metric of a processing resource utilized to perform a static validation of the IC designs.

9. The method of claim 1, wherein the design features relate to:
a number of instances;
pins;
ports;
nets;
a number of hierarchies;
a number of libraries;
macro cells;
pad cells; and/or
power management cells.

10. The method of claim 1, wherein the training comprises:
multiple linear regression based supervised training.

11. A system, comprising:
a memory; and
a processing device coupled with the memory, the processing device configured to,
extract design features of a training set of integrated circuit (IC) designs;
select a one or more of the extracted design features based on an extent to which the extracted design features correlate to a metric of a processing resource utilized to evaluate the IC designs;
select one or more auxiliary features of the IC designs based on an extent to which the auxiliary features correlate to the metric of the processing resource utilized to evaluate the IC designs; and
train an artificial intelligence/machine learning (AI/ML) model to correlate a combination of the selected design features of the IC design and the selected auxiliary features of the new IC design with the metric of the processing resource utilized to evaluate the IC designs.

12. The system of claim 11, wherein the processing device is further configured to:
extract the selected design features from a new IC design;
use the trained model to predict the metric for the new IC design based on the selected design features extracted from the new IC design and the selected auxiliary features of the new IC design.

13. The system of claim 11, wherein the metric comprises a memory metric and/or a runtime metric.

14. The system of claim 11, wherein the processing device is configured to:
select one or more of multiple computing platforms on which to evaluate the new IC design based on the predicted metric and specifications of the computing platforms.

15. The system of claim 11, wherein the processing device is configured to:
segment the IC design into sub-blocks;
use the trained model to predict the metric for the sub-blocks of the new IC design; and
select one or more of multiple computing platforms on which to evaluate the sub-blocks based on the predicted metrics of the sub-blocks and specifications of the computing platforms.

16. A non-transitory computer readable medium comprising instructions, which when executed by a processing device, cause the processing device to:
extract design features of a training set of integrated circuit (IC) designs,
select a one or more of the extracted features based on an extent to which the extracted design features correlate to a metric of a processing resource utilized to evaluate the IC designs,
select one or more auxiliary features of the IC designs based on an extent to which the auxiliary features correlate to the metric of the processing resource utilized to evaluate the IC designs;
train a machine learning (ML) model to correlate a combination of the selected design features of the IC designs and the selected auxiliary features of the IC designs with the metric of the IC designs,
extract the selected design features from a new IC design, and
use the trained model to predict the metric for the new IC design based on the combination of the selected design features of the new IC design and the selected auxiliary features of the new IC design.

17. The non-transitory computer readable medium of claim 16, wherein the metric comprises a memory metric and/or a runtime metric.

18. The non-transitory computer readable medium of claim 16, wherein the computing platform is further configured to:
select one or more of multiple computing platforms on which to evaluate the new IC design based on the predicted metric and specifications of the computing platforms.

19. The non-transitory computer readable medium of claim 16, wherein the computing platform is further configured to:
segment the IC design into sub-blocks;
use the trained model to predict the metric for the sub-blocks of the new IC design; and
select one or more of multiple computing platforms on which to evaluate the sub-blocks based on the predicted metrics of the subblocks and specifications of the computing platforms.

20. The non-transitory computer readable medium of claim 16, wherein the computing platform is further configured to:
train the ML model with a multiple linear regression technique.
